(19) United States
(12) Patent Application Publication
(10) Pub. No.: US 2020/0356001 A1
(43) Pub. Date: Nov. 12, 2020

(54) PHOTORESIST COMPOSITIONS AND METHODS OF FORMING RESIST PATTERNS WITH SUCH COMPOSITIONS

(71) Applicant: Rohm and Haas Electronic Materials LLC, Marlborough, MA (US)

(72) Inventors: Tomas Marangoni, Marlborough, MA (US); Mingqi Li, Shrewsbury, MA (US); Jong Keun Park, Westborough, MA (US); Emad Aqad, Northborough, MA (US); Xisen Hou, Lebanon, NH (US); James F. Cameron, Brookline, MA (US)

(21) Appl. No.: 16/409,093

(22) Filed: May 10, 2019

(51) Int. Cl. G03F 7/004; C08L 25/08; G03F 7/20; G03F 7/039; C08K 5/46

(52) U.S. Cl. CPC G03F 7/0045; C08L 25/08; C08K 5/46; G03F 7/0041; G03F 7/0392; G03F 7/2039

(57) ABSTRACT

A photoresist composition, including a polymer having a C₆₋₃₀ hydroxyaromatic group, a solvent, and a sulfonium salt having Formula (I):

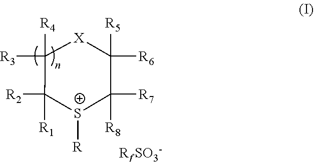

wherein, in Formula (I), R, R¹ to R⁸, X, n, and R_{f} are the same as described in the specification.

### FIELD

The present disclosure relates to a photoresist composition and a chemically amplified photoresist (CAR) formed from the photoresist composition. Specifically, the disclosure relates to a chemically amplified photoresist having a thickness of greater than 5 microns.

### INTRODUCTION

The Integrated Circuit (IC) industry has achieved the low cost of a bit by going towards smaller geometries. However, further miniaturization of the critical dimensions could not be realized by current lithographic techniques with similarly low production cost. NAND flash manufacturers have been looking into techniques for stacking multiple layers of memory cells to achieve greater storage capacity while still maintaining lower manufacturing cost per bit. Such 3D NAND devices are denser, faster; and less expensive than the traditional 2D planar NAND devices.

The 3D NAND architecture comprises vertical channel and vertical gate architectures, and the stepped structure (known as “staircase”) is used to form an electrical connection between memory cells and bit lines or word lines. In constructing 3D NAND flash memories, manufacturers increase the number of stairs using a thick resist that allows for multiple trimming and etching cycles used for staircase formation. Maintaining good feature profile on each step is challenging since subsequent trimming-etching variations on critical dimension (CD) will be accumulated step by step and across the wafer.

The process of “staircase” formation that calls for the use of a single mask exposure of a thick KrF photo-resist to form several sets of stairs is considered as a relatively cost-effective approach. The application requires a photoresist thickness of 5 to 30 microns, for example, 8 to 30 microns or 8 to 25 microns. However, conventional KrF photoresists described in the literature are only designed for applications that require a much lower nanometer scale resist film thickness.

Chemically amplified resist compositions should possess desirable optical properties to enable image resolution at a desired wavelength. To achieve acceptable pattern profile, incident radiation should reach the bottom of the film during exposure. However, known lithographic resist compositions do not meet the transparency requirement at the thick film thickness needed for printing of acceptable features. Therefore, there is a need for more transparent resist compositions for the lithographic patterning thick resist films. The resist composition should also possess suitable chemical and mechanical properties to enable image transfer from patterned resist to the underlying substrate layer(s). Patterning applications that employ positive tone thick film resists require enhanced dissolution rate in an aqueous alkaline developer.

Having highly transparent photoresists is extremely desirable, since it enables printing patterns with better profile integrity and better Critical Dimension Uniformity (CDU). This requirement is of particular importance for thick photoresists, which are patterned, for example, using a KrF excimer laser. For this type of exposure, compositions that include imaging polymers together with a photoacid generator (PAG) are generally used to form patternable photoresist compositions. However, known photoresist compositions possess low optical transparency due to the high absorbance contributed mainly by the photoacid generator chromophore. Typical photoacid generator chromophores are derived from onium salts. When irradiated, these salts form strong acids that catalyze polymer deprotection. A problem can occur in thick film photoresists, where the high absorption of onium salt PAGs does not allow optimal light penetration into the bottom part of the film. This leads to scumming, poor control over the patterned features, and generation of pattern defects. Examples of photoacid generators having high optical transparency have been reported. However, these photoacid generators are known to lead to very low sensitivity in comparison to the less transparent analogues. Therefore, a strong need remains for new chemical compositions that could be suitable as thick photoresists, which are transparent and possess high sensitivity, at the same time.

### SUMMARY

In an embodiment, a composition for a thick photoresist is provided. The photoresist composition includes:

a polymer;

a solvent; and

a sulfonium salt having Formula (I):

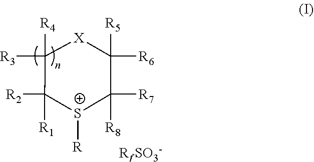

wherein:

R is an unsubstituted or substituted C₂₋₂₀ alkenyl group, an unsubstituted or substituted C₃₋₂₀ cycloalkyl group, an unsubstituted or substituted C₅₋₃₀ aromatic group, or an unsubstituted or substituted C₄₋₃₀ heteroaromatic group, wherein R optionally includes an acid-sensitive functional group capable of being hydrolyzed at pH<7.0;

R₁ to R₈ are each independently hydrogen, a halogen selected from fluorine, chlorine, bromine, and iodine, a straight chain or branched C₁₋₂₀ alkyl group, a straight chain or branched C₁₋₂₀ fluoroalkyl group, a straight chain or branched C₂₋₂₀ alkenyl group, a straight chain or branched C₂₋₂₀ fluoroalkenyl group, a monocyclic or polycyclic C₃₋₂₀ cycloalkyl group, a monocyclic or polycyclic C₃₋₂₀ fluorocycloalkyl group, a monocyclic or polycyclic C₃₋₂₀ cycloalkenyl group, a monocyclic or polycyclic C₃₋₂₀ fluorocycloalkenyl group, a monocyclic or polycyclic C₃₋₂₀ heterocycloalkyl group; a monocyclic or polycyclic C₃₋₂₀ heterocycloalkenyl group; a monocyclic or polycyclic C₆₋₂₀ aryl group, a monocyclic or polycyclic C₆₋₂₀ fluoroaryl group, a monocyclic or polycyclic C₄₋₂₀ heteroaryl group, or a monocyclic or polycyclic C₄₋₂₀ fluoroheteroaryl group, each of which except hydrogen is substituted or unsubstituted,

wherein any two of R₁ to R₈ are optionally connected via Z to form a ring, wherein Z is a single bond or at least one linker selected from —C(═O)—, —S(═O)—, —S(═O)₂—, —C(═O)O—, —C(═O)NR′—, —C(═O)—C(═O)—, —O—, —CH(OH)—, —CH₂—, —S—, and —BR′—, wherein R′ is hydrogen or a C₁₋₂₀ alkyl group,

wherein each of R₁ to R₈ are optionally substituted with at least one selected from —OY, —NO₂, —CF₃, —C(═O)—C(═O)—Y, —CH₂OY, —CH₂Y, —SY, —B(Y)ₙ, —C(═O)NRY, —NRC(═O)Y, —(C═O)OY, and —O(C═O)Y, wherein Y is a straight chain or branched C₁₋₂₀ alkyl group, a straight chain or branched C₁₋₂₀ fluoroalkyl group, a straight chain or branched C₂₋₂₀ alkenyl group, a straight chain or branched C₂₋₂₀ fluoroalkenyl group, a straight chain or branched C₂₋₂₀ alkynyl group, a straight chain or branched C₂₋₂₀ fluoroalkynyl group, a C₆₋₂₀ aryl group, a C₆₋₂₀ fluoroaryl group, or an acid-sensitive functional group capable of being hydrolyzed at pH<7.0;

X is O, S, Se, Te, NR″, S═O, S(═O)₂, C═O, (C═O)O, O(C═O), (C═O)NR″, or NR″(C═O), wherein R″ is hydrogen or a C₁₋₂₀ alkyl group;

n is an integer of 0 to 5; and

R_{f} is a linear or branched or cyclic C₁₋₆ fluorinated alkyl group.

In another embodiment, a coated substrate is provided. The coated substrate includes: (a) a substrate having one or more layers to be patterned on a surface thereof; and (b) a layer of the above photoresist composition over the one or more layers to be patterned.

In yet another embodiment, a method of forming a resist pattern is provided. The method includes: (a) applying a layer of the above photoresist composition on a substrate; (b) drying the applied resist composition to form a composition layer; (c) exposing the composition layer to activating radiation; (d) heating the exposed composition layer; and (e) developing the exposed composition layer.

### BRIEF DESCRIPTION OF THE DRAWINGS

The above and other aspects and features of the present disclosure will become more apparent by describing in detail exemplary embodiments thereof with reference to the attached drawings, in which:

FIGS. 1A to 1K are representative diagrams schematically showing steps of a method of forming a staircase pattern in accordance with the invention; and

FIG. 2 is a table showing results of the KrF lithographic studies.

### DETAILED DESCRIPTION

Reference will now be made in detail to exemplary embodiments, examples of which are illustrated in the accompanying drawings, wherein like reference numerals refer to like elements throughout. In this regard, the present exemplary embodiments may have different forms and should not be construed as being limited to the descriptions set forth herein. Accordingly, the exemplary embodiments are merely described below, by referring to the figures, to explain aspects of the present inventive concept. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “on” another element, it can be directly in contact with the other element or intervening elements may be present therebetween. In contrast, when an element is referred to as being “directly on” another element, there are no intervening elements present.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

The terminology used herein is for the purpose of describing particular embodiments only and is not intended to be limiting. As used herein, the singular forms “a,” “an,” and “the” are intended to include the plural forms as well, unless the context clearly indicates otherwise.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, when a definition is not otherwise provided, the term “alkyl group” refers to a group derived from a straight or branched chain saturated aliphatic hydrocarbon having the specified number of carbon atoms and having a valence of at least one.

As used herein, when a definition is not otherwise provided, the term “fluoroalkyl group” refers to an alkyl group in which at least one hydrogen atom is replaced with a fluorine atom.

As used herein, when a definition is not otherwise provided, the term “alkenyl group” refers to a group derived from a straight or branched chain unsaturated aliphatic hydrocarbon including at least one double bond, having the specified number of carbon atoms, and having a valence of at least one.

As used herein, when a definition is not otherwise provided, the term “fluoroalkenyl group” refers to an alkenyl group in which at least one hydrogen atom is replaced with a fluorine atom.

As used herein, when a definition is not otherwise provided, the term “alkynyl group” refers to a group derived from a straight or branched chain unsaturated aliphatic hydrocarbon including at least one triple bond, having the specified number of carbon atoms, and having a valence of at least one.

As used herein, when a definition is not otherwise provided, the term “fluoroalkynyl group” refers to an alkynyl group in which at least one hydrogen atom is replaced with a fluorine atom.

As used herein, when a definition is not otherwise provided, the term “cycloalkyl group” refers to a monovalent group having one or more saturated rings in which all ring members are carbon.

As used herein, when a definition is not otherwise provided, the term “fluorocycloalkyl group” refers to a cycloalkyl group in which at least one hydrogen atom is replaced with a fluorine atom.

As used herein, when a definition is not otherwise provided, the term “cycloalkenyl group” refers to a group derived from a straight or branched chain unsaturated alicyclic hydrocarbon including at least one double bond, having the specified number of carbon atoms, and having a valence of at least one.

As used herein, when a definition is not otherwise provided, the term “fluorocycloalkenyl group” refers to a cycloalkenyl group in which at least one hydrogen atom is replaced with a fluorine atom.

As used herein, when a definition is not otherwise provided, the term “heterocycloalkyl group” refers to a monovalent saturated cyclic group that has atoms of at least two different elements as members of its ring(s), one of which is carbon.

As used herein, when a definition is not otherwise provided, the term “heterocycloalkenyl group” refers to a monovalent unsaturated cyclic group that has atoms of at least two different elements as members of its ring(s), one of which is carbon.

As used herein, when a definition is not otherwise provided, the term “aryl”, which is used alone or in combination, refers to an aromatic hydrocarbon containing at least one ring and having the specified number of carbon atoms. The term “aryl” may be construed as including a group with an aromatic ring fused to at least one cycloalkyl ring.

As used herein, when a definition is not otherwise provided, the term “fluoroaryl group” refers to an aryl group in which at least one hydrogen atom is replaced with a fluorine atom.

As used herein, when a definition is not otherwise provided, the term “heteroaryl”, which is used alone or in combination, refers to an aromatic hydrocarbon containing at least one ring that has atoms of at least two different elements as members of its ring(s), one of which is carbon, and having the specified number of carbon atoms.

As used herein, when a definition is not otherwise provided, the term “fluoroheteroaryl group” refers to a fluoroheteroaryl group in which at least one hydrogen atom is replaced with a fluorine atom.

As used herein, when a definition is not otherwise provided, the term “substituted” means including at least one substituent such as a halogen (F, Cl, Br, I), hydroxyl, amino, thiol, ketone, anhydride, sulfone, sulfoxide, sulfonamide, carboxyl, carboxylate, ester (including acrylates, methacrylates, and lactones), amide, nitrile, sulfide, disulfide, nitro, C₁₋₂₀ alkyl, C₃₋₂₀ cycloalkyl (including adamantyl), C₁₋₂₀ alkenyl (including norbornenyl), C₁₋₂₀ alkoxy, C₂₋₂₀ alkenoxy (including vinyl ether), C₆₋₃₀ aryl, C₆₋₃₀ aryloxy, C₇₋₃₀ alkylaryl, or C₇₋₃₀ alkylaryloxy.

When a group containing a specified number of carbon atoms is substituted with any of the groups listed in the preceding paragraphs, the number of carbon atoms in the resulting “substituted” group is defined as the sum of the carbon atoms contained in the original (unsubstituted) group and the carbon atoms (if any) contained in the substituent. For example, when the term “substituted C₁-C₂₀ alkyl” refers to a C₁-C₂₀ alkyl group substituted with C₆-C₃₀ aryl group, the total number of carbon atoms in the resulting aryl substituted alkyl group is C₇-C₅₀.

As used herein, when the definition is not otherwise provided, the term “mixture” refers to any combination of the ingredients constituting the blend or mixture without regard to a physical form.

As noted above, it is generally difficult to obtain a film coating possessing high optical transparency to the pattering radiation and suitable mechano-physical properties to enable a good substrate coating and image transfer to the underlying layer. High optical transparency is particularly important for thick photoresists, which are patterned using a KrF excimer laser.

Disclosed herein is a new photoresist composition designed for thick film patterning. The new composition possesses unexpectedly high optical transparency at 248 nm and improved photospeed and lithographic performance.

In an embodiment, the photoresist composition may include a polymer, a solvent, and a sulfonium salt.

The polymer may include a C₆₋₃₀ hydroxyaromatic group, for example, a hydroxyphenyl group or a hydroxynaphthyl group. In an embodiment, the polymer may include a structural unit represented by Formula (A-1):

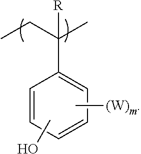

(A-1)

In Formula (A-1),

R may be hydrogen, a C₁₋₂₀ alkyl group, a C₁₋₂₀ fluoroalkyl group, a C₆₋₂₀ aryl group, or a C₆₋₂₀ fluoroaryl group, each of which except hydrogen may be substituted or unsubstituted;

W may be hydrogen, a halogen selected from fluorine, chlorine, bromine, and iodine, a carboxylic acid or ester, an hydroxy group, a thiol, a straight chain or branched C₁₋₂₀ alkyl group, a straight chain or branched C₁₋₂₀ fluoroalkyl group, a straight chain or branched C₂₋₂₀ alkenyl group, a straight chain or branched C₂₋₂₀ fluoroalkenyl group, a monocyclic or polycyclic C₃₋₂₀ cycloalkyl group, a monocyclic or polycyclic C₃₋₂₀ fluorocycloalkyl group, a monocyclic or polycyclic C₃₋₂₀ cycloalkenyl group, a monocyclic or polycyclic C₃₋₂₀ fluorocycloalkenyl group, a monocyclic or polycyclic C₃₋₂₀ heterocycloalkyl group; a monocyclic or polycyclic C₃₋₂₀ heterocycloalkenyl group; a monocyclic or polycyclic C₆₋₂₀ aryl group, or a monocyclic or polycyclic C₄₋₂₀ heteroaryl group, each of which except hydrogen may be substituted or unsubstituted, and

m may be an integer of 0 to 4.

In Formula (A-1), the hydroxyl group may be present at either the ortho, meta, or para positions throughout the polymer. When m is 2 or more, groups W may be the same or different, and may be optionally connected to form a ring.

The polymer may have a molecular weight (M_{w}) from about 8,000 Daltons (Da) to about 50,000 Da, for example, from about 15,000 Da to about 30,000 Da with a molecular distribution of about 3 or less, for example, 2 or less.

In some embodiments, the polymer may include structural units formed from a substituted or unsubstituted styrene monomer in an amount of equal to or greater than about 50 weight percent, for example, equal to or greater than about 60 weight percent, equal to or greater than about 70 weight percent, equal to or greater than about 80 weight percent, equal to or greater than about 90 weight percent, or equal to or greater than about 95 weight percent, based on 100 weight percent of the total amount of structural units in the polymer.

The composition may further include a solvent. The solvent may be an aliphatic hydrocarbon (such as hexane, heptane, and the like), an aromatic hydrocarbon (such as toluene, xylene, and the like), a halogenated hydrocarbon (such as dichloromethane, 1,2-dichloroethane, 1-chlorohexane, and the like), an alcohol (such as methanol, ethanol, 1-propanol, iso-propanol, tert-butanol, 2-methyl-2-butanol, 4-methyl-2-pentanol, and the like), water, an ether (such as diethyl ether, tetrahydrofuran, 1,4-dioxane, anisole, and the like), a ketone (such as acetone, methyl ethyl ketone, methyl iso-butyl ketone, 2-heptanone, cyclohexanone, and the like), an ester (such as ethyl acetate, n-butyl acetate, propylene glycol monomethyl ether acetate (PGMEA), ethyl lactate, hydroxyisobutyrate methyl ester (HBM), ethyl acetoacetate, and the like), a lactone (such as gamma-butyrolactone (GBL), epsilon-caprolactone, and the like), a nitrile (such as acetonitrile, propionitrile, and the like), aa polar aprotic solvent (such as dimethyl sulfoxide, dimethyl formamide, and the like), or a combination thereof.

The composition may further include a sulfonium salt. In an embodiment, the sulfonium salt may be represented by Formula (I):

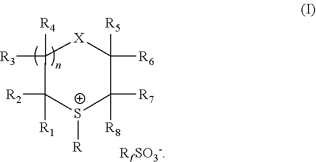

In Formula (I), R may be an unsubstituted or substituted C₂₋₂₀ alkenyl group, an unsubstituted or substituted C₃₋₂₀ cycloalkyl group, an unsubstituted or substituted C₅₋₃₀ aromatic group, or an unsubstituted or substituted C₄₋₃₀ heteroaromatic group. A non-limiting example of the C₂₋₂₀ alkenyl group may be a vinyl group or an allyl group, each of which may be unsubstituted or substituted. A non-limiting example of the C₃₋₂₀ cycloalkyl group may be a cyclopropyl group, a cyclobutyl group, a cyclopentyl group, a cyclohexyl group, a cycloheptyl group, or a cyclooctyl group, each of which may be unsubstituted or substituted. The C₅₋₃₀ aromatic group may be a monocyclic aromatic group or a polycyclic aromatic group which may include fused aromatic rings or singly bonded aromatic rings. A non-limiting example of the monocyclic aromatic group may be a phenyl group. A non-limiting example of the polycyclic aromatic group may be a naphthyl group or a biphenyl group. A C₄₋₃₀ heteroaromatic group may be a monocyclic heteroaromatic group or a polycyclic heteroaromatic group which may include fused aromatic rings or singly bonded aromatic rings. A non-limiting example of the monocyclic heteroaromatic group may be a thienyl group or a pyridyl group. A non-limiting example of the polycyclic aromatic group may be a quinolinyl group.

In some embodiments, R may be a phenyl group substituted with one or more C₁₋₃₀ alkyl or C₃₋₈ cycloalkyl, for example, C₁₋₅ alkyl or C₃₋₆ cycloalkyl. For example, the phenyl group may be substituted with a plurality of such alkyl or cycloalkyl groups.

In some embodiments, R may optionally include an acid-sensitive functional group capable of being hydrolyzed at pH<7.0, for example, a tertiary ester, a tertiary ether or a tertiary carbonate group. In other embodiments, R may be an unsubstituted or substituted C₅₋₃₀ aromatic group or an unsubstituted or substituted C₄₋₃₀ heteroaromatic group. For example, R may be a substituted phenyl group.

In Formula (I), R₁ to R₈ may be the same or different, and may each independently be hydrogen, a halogen selected from fluorine, chlorine, bromine, and iodine, a straight chain or branched C₁₋₂₀ alkyl group, a straight chain or branched C₁₋₂₀ fluoroalkyl group, a straight chain or branched C₂₋₂₀ alkenyl group, a straight chain or branched C₂₋₂₀ fluoroalkenyl group, a monocyclic or polycyclic C₃₋₂₀ cycloalkyl group, a monocyclic or polycyclic C₃₋₂₀ fluorocycloalkyl group, a monocyclic or polycyclic C₃₋₂₀ cycloalkenyl group, a monocyclic or polycyclic C₃₋₂₀ fluorocycloalkenyl group, a monocyclic or polycyclic C₃₋₂₀ heterocycloalkyl group; a monocyclic or polycyclic C₃₋₂₀ heterocycloalkenyl group; a monocyclic or polycyclic C₆₋₂₀ aryl group, a monocyclic or polycyclic C₆₋₂₀ fluoroaryl group, a monocyclic or polycyclic C₄₋₂₀ heteroaryl group, or a monocyclic or polycyclic C₄₋₂₀ fluoroheteroaryl group, each of which except hydrogen may be substituted or unsubstituted. In some embodiments, each of R₁ to R₈ may be hydrogen.

Any two of R₁ to R₈ may be optionally connected via Z to form a ring, wherein Z may be a single bond or at least one linker selected from —C(═O)—, —S(═O)—, —S(═O)₂—, —C(═O)O—, —C(═O)NR′—, —C(═O)—C(═O)—, —O—, —CH(OH)—, —CH₂—, —S—, and —BR′—, wherein R′ may be hydrogen or a C₁₋₂₀ alkyl group.

Each of R₁ to R₈ may be optionally substituted with at least one selected from —OY, —NO₂, —CF₃, —C(═O)—C(═O)—Y, —CH₂OY, —CH₂Y, —SY, —B(Y)ₙ, —C(═O)NRY, —NRC(═O)Y, —(C═O)OY, and —O(C═O)Y, wherein Y is a straight chain or branched C₁₋₂₀ alkyl group, a straight chain or branched C₁₋₂₀ fluoroalkyl group, a straight chain or branched C₂₋₂₀ alkenyl group, a straight chain or branched C₂₋₂₀ fluoroalkenyl group, a straight chain or branched C₂₋₂₀ alkynyl group, a straight chain or branched C₂₋₂₀ fluoroalkynyl group, a C₆₋₂₀ aryl group, a C₆₋₂₀ fluoroaryl group, or an acid-sensitive functional group capable of being hydrolyzed at pH<7.0, such as a tertiary ester, tertiary ether or tertiary carbonate group.

In Formula (I), X may be a divalent linking group such as O, S, Se, Te, NR″, S═O, S(═O)₂, C═O, (C═O)O, O(C═O), (C═O)NR″, or NR″(C═O), wherein R″ may be hydrogen or a C₁₋₂₀ alkyl group. n may be an integer of 0, 1, 2, 3, 4, and 5. In some embodiments, X may be O.

Non-limiting examples of cations

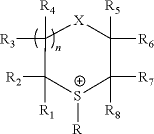

may include the following sulfonium cations:

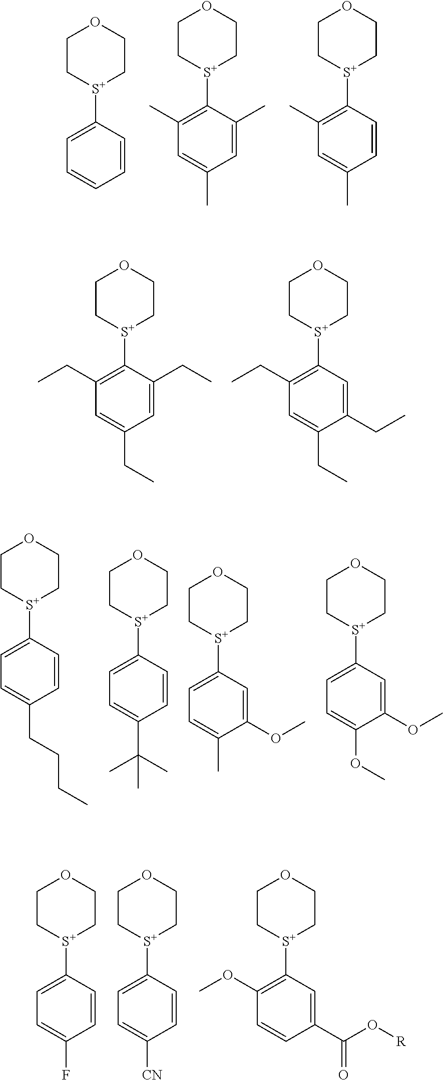

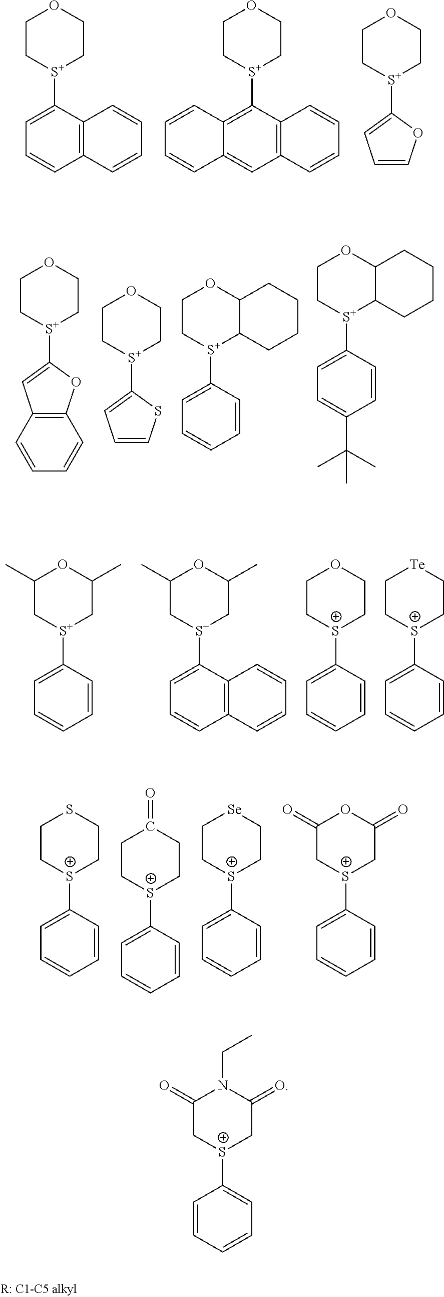

In Formula (I), R_{f}SO₃⁻ is a fluorinated sulfonate anion, wherein R_{f} is a fluorinated group. In an embodiment, R_{f} may be —C(R₉)_{y}(R₁₀)_{z}, wherein R₉ may be independently selected from F and fluorinated methyl, R₁₀ may be independently selected from H, C₁₋₅ linear or branched or cycloalkyl and C₁₋₅ linear or branched or cyclic fluorinated alkyl, y and z may be independently an integer from 0 to 3, provided that the sum of y and z is 3 and at least one of R₉ and R₁₀ contains fluorine, wherein the total number of carbon atoms in R_{f} may be from 1 to 6. In the formula —C(R₉)_{y}(R₁₀)_{z}, both R₉ and R₁₀ are attached to C. Preferably, there is at least one fluorine atom or fluorinated group bonded to the carbon atom at the alpha position with respect to the SO₃⁻ group. In some embodiments, y may be 2, and z may be 1. In these embodiments, each R₉ may be F, or one R₉ may be F and the other R₉ may be fluorinated methyl. A fluorinated methyl may be monofluoromethyl (—CH₂F), difluoromethyl (—CHF₂), and trifluoromethyl (—CF₃). In some other embodiments, R₁₀ may be independently selected from C₁₋₅ linear or branched fluorinated alkyl. A fluorinated alkyl may be perfluorinated alkyl. Non-limiting examples of R_{f}SO₃⁻ may include the following anions:

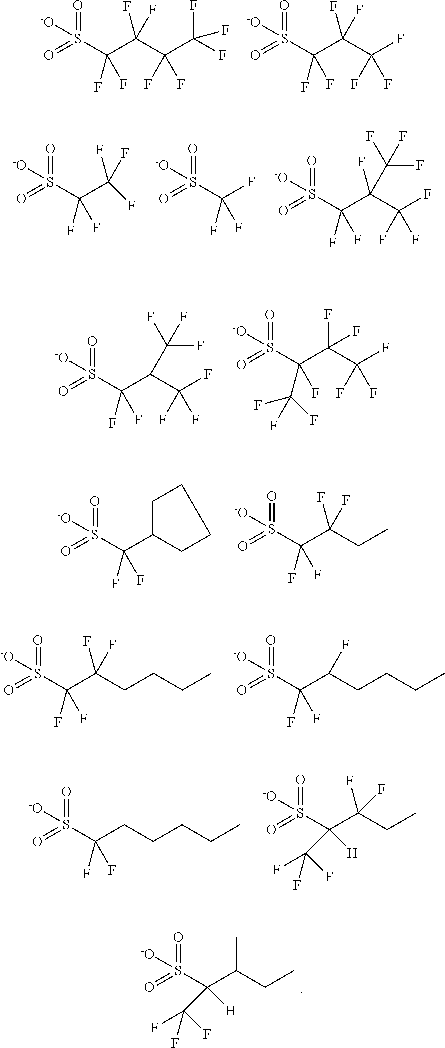

The sulfonium salt having Formula (I) is a photoacid generator, which possesses a unique combination of desired properties that makes it attractive for use in thick layer photoresists. Because of the low number of aromatic groups, the photoacid generator exhibits unexpectedly high transparency. The relatively small volume of the anion containing only 1 to 6 carbon atoms enables the photoacid generator to generate a fast diffusing photoacid (R_{f}SO₃H). The latter properties allows for efficient acid-catalyzed deprotection events during post exposure bake (PEB), which in turn leads to enhanced dissolution properties during the development step. The oxathianium cation core adds to high stability and unexpectedly longer shelf life of the photoresist, compared to conventional products. The sulfonium salt having Formula (I) also has excellent solubility in organic solvents.

The photoresist composition may further include a basic quencher. Suitable basic quenchers may, for example, include: linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one and tert-butyl 1,3-dihydroxy-2-(hydroxymethyl)propan-2-ylcarbamate; aromatic amines such as pyridine, and 2,6-di-tert-butyl pyridine; aliphatic amines such as triisopropanolamine, n-tert-butyldiethanolamine, tris(2-acetoxy-ethyl) amine, 2,2′,2″,2″-(ethane-1,2-diylbis(azanetriyl))tetraethanol, and 2-(dibutylamino)ethanol, 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate and N-(2-acetoxy-ethyl)morpholine. Of these basic quenchers, 1-(tert-butoxycarbonyl)-4-hydroxypiperidine and triisopropanolamine are preferred, but the base is not limited thereto. The added base is suitably used in relatively small amounts, for example, from 0.1 to 20 weight % relative to the PAG, more typically, from 1 to 15 weight % relative to the PAG.

The photoresist composition may include other optional ingredients such as one or more surface levelling agents (SLA) and/or plasticizers. If present in the composition, the SLA is preferably present in an amount from 0.001 to 0.1 weight percent based on total solids of the composition, and the plasticizer is preferably present in an amount from 0.1 to 15 weight percent based on total solids of the composition.

The photoresist composition including the polymer and the sulfonium salt having Formula (I) as disclosed herein may be coated in a single application to provide a thick photoresist layer. The thickness of the photoresist layer may be greater than about 5 microns, for example, greater than about 5 microns and less than 30 microns, greater than 6 microns and less than 30 microns, greater than 7 microns and less than 30 microns, greater than 8 microns and less than 30 microns, greater than 9 microns and less than 30 microns, greater than 10 microns and less than 30 microns, greater than 15 microns and less than 30 microns, greater than 20 microns and less than 30 microns, or greater than 25 microns and less than 30 microns. In some embodiments, the thickness of the photoresist layer may be about 6 microns, about 7 microns, about 8 microns, about 9 microns, or about 10 microns. In some embodiments, the photoresist composition may be capable of being coated in a single application to a thickness in a dried state of greater than 5.0 microns and less than 30 microns. As used herein, the “dried state” refers to the photoresist composition comprising 25 weight percent or less of the solvent, for example, 12 weight percent or less of the solvent, 10 weight percent or less of the solvent, 8 weight percent or less of the solvent, or 5 weight percent or less of the solvent, based on the total weight of the photoresist composition.

A coated substrate may be formed from the photoresist composition. Such a coated substrate may include: (a) a substrate, and (b) a layer of the photoresist composition disposed over the substrate.

Substrates may be any dimension and shape, and are preferably those useful for photolithography, such as silicon, silicon dioxide, silicon-on-insulator (SOI), strained silicon, gallium arsenide, coated substrates including those coated with silicon nitride, silicon oxynitride, titanium nitride, tantalum nitride, ultrathin gate oxides such as hafnium oxide, metal or metal coated substrates including those coated with titanium, tantalum, copper, aluminum, tungsten, alloys thereof, and combinations thereof. Preferably, the surfaces of substrates herein include critical dimension layers to be patterned including, for example, one or more gate-level layers or other critical dimension layers on the substrates for semiconductor manufacture. Such substrates may preferably include silicon, SOT, strained silicon, and other such substrate materials, formed as circular wafers having dimensions such as, for example, 20 cm, 30 cm, or larger in diameter, or other dimensions useful for wafer fabrication production.

Further, a method of forming an electronic device may include: (a) applying a layer of the photoresist composition on a substrate; (b) drying the applied photoresist composition to form a composition layer; (c) exposing the composition layer to activating radiation; (d) heating the exposed composition layer; and (e) developing the exposed composition layer. The method may further include etching a plurality of steps into the substrate.

Application of the photoresist may be accomplished by any suitable method, including spin coating, spray coating, dip coating, doctor blading, or the like. For example, applying the layer of photoresist may be accomplished by spin-coating the photoresist in solvent using a coating track, in which the photoresist is dispensed on a spinning wafer. During dispensing, the wafer may be spun at a speed of up to 4,000 rpm, for example, from about 200 to 3,000 rpm, for example, 1,000 to 2,500 rpm. The coated wafer is spun to remove solvent, and soft-baked on a hot plate to remove residual solvent and reduce free volume to densify the film. The soft-bake temperature is typically from 90 to 170° C., for example, from 110 to 150° C. The heating time is typically from 10 seconds to 20 minutes, for example, from 1 minute to 10 minutes, or from 1 minute to 5 minutes. The heating time can be readily determined by one of ordinary skill in the art based on the ingredients of the composition.

The casting solvent can be any suitable solvent known to one of ordinary skill in the art. For example, the casting solvent can be an aliphatic hydrocarbon (such as hexane, heptane, and the like), an aromatic hydrocarbon (such as toluene, xylene, and the like), a halogenated hydrocarbon (such as dichloromethane, 1,2-dichloroethane, 1-chlorohexane, and the like), an alcohol (such as methanol, ethanol, 1-propanol, iso-propanol, tert-butanol, 2-methyl-2-butanol, 4-methyl-2-pentanol, and the like), water, an ether (such as diethyl ether, tetrahydrofuran, 1,4-dioxane, anisole, and the like), a ketone (such as acetone, methyl ethyl ketone, methyl iso-butyl ketone, 2-heptanone, cyclohexanone, and the like), an ester (such as ethyl acetate, n-butyl acetate, propylene glycol monomethyl ether acetate (PGMEA), ethyl lactate, hydroxyisobutyrate methyl ester (HBM), ethyl acetoacetate, and the like), a lactone (such as gamma-butyrolactone (GBL), epsilon-caprolactone, and the like), a nitrile (such as acetonitrile, propionitrile, and the like), a polar aprotic solvent (such as dimethyl sulfoxide, dimethyl formamide, and the like), or a combination thereof. The choice of the casting solvent depends on a particular photoresist composition and can be readily made by one of ordinary skill in the art based on knowledge and experience. The composition may then be dried by using conventional drying methods known to one of ordinary skill in the art.

The photoresist composition may be prepared by dissolving the polymer, the sulfonium salt and any optional components in the appropriate amounts in the casting solvent. The photoresist composition or one or more of the components of the photoresist composition can be optionally subjected to a filtration step and/or ion exchange process using an appropriate ion exchange resin for purification purposes.

Exposure is then carried out using an exposure tool such as a stepper or scanner, in which the film is irradiated through a pattern mask and thereby is exposed pattern-wise. The method may use advanced exposure tools generating activating radiation at wavelengths capable of high-resolution patterning including excimer lasers, such as Krypton Fluoride laser (KrF). It will be appreciated that exposure using the activating radiation decomposes the PAG in the exposed areas and generates acid, and that the acid then effectuates a chemical change in the polymer (deblocking the acid sensitive group to generate a base-soluble group, or alternatively, catalyzing a crosslinking reaction in the exposed areas). The resolution of such exposure tools may be less than 30 nm.

Heating of the exposed composition may take place at a temperature of about 100° C. to about 150° C., for example, about 110° C. to about 150° C., about 120° C. to about 150° C., about 130° C. to about 150° C., or about 140° C. to about 150° C. The heating time may vary from about 30 seconds to about 20 minutes, for example, from about 1 minute to about 10 minute, or from about 1 minute to about 5 minutes. The heating time can be readily determined by one of ordinary skill in the art based on the ingredients of the composition.

Developing the exposed photoresist layer is then accomplished by treating the exposed layer with a suitable developer capable of selectively removing the exposed portions of the film (where the photoresist is a positive tone) or removing the unexposed portions of the film (where the photoresist is cross-linkable in the exposed regions, i.e., a negative tone). Typical developers include aqueous quaternary ammonium hydroxide solutions such as tetramethylammonium hydroxide (TMAH), typically 0.26N TMAH, tetraethylammonium hydroxide and tetrabutyl ammonium hydroxide, sodium hydroxide, potassium hydroxide, sodium carbonate, potassium carbonate, and the like. A pattern then forms by developing. A solvent develop process can be used with any suitable developer known in the art. For example, the solvent developer can be an aliphatic hydrocarbon (such as hexane, heptane, and the like), an aromatic hydrocarbon (such as toluene, xylene, and the like), a halogenated hydrocarbon (such as dichloromethane, 1,2-dichloroethane, 1-chlorohexane, and the like), an alcohol (such as methanol, ethanol, 1-propanol, iso-propanol, tert-butanol, 2-methyl-2-butanol, 4-methyl-2-pentanol, and the like), water, an ether (such as diethyl ether, tetrahydrofuran, 1,4-dioxane, anisole, and the like), a ketone (such as acetone, methyl ethyl ketone, methyl iso-butyl ketone, 2-heptanone, cyclohexanone, and the like), an ester (such as ethyl acetate, n-butyl acetate (nBA), propylene glycol monomethyl ether acetate (PGMEA), ethyl lactate (EL), hydroxyisobutyrate methyl ester (HBM), ethyl acetoacetate, and the like), a lactone (such as gamma-butyrolactone (GBL), epsilon-caprolactone, and the like), a nitrile (such as acetonitrile, propionitrile, and the like), a polar aprotic solvent (such as dimethyl sulfoxide, dimethyl formamide, and the like), or a combination thereof. In an embodiment, the solvent developer may be a miscible mixture of solvents, for example, a mixture of an alcohol (iso-propanol) and ketone (acetone). The choice of the developer solvent depends on a particular photoresist composition and can be readily made by one of ordinary skill in the art based on knowledge and experience.

The photoresist may, when used in one or more such pattern-forming processes, be used to fabricate electronic and optoelectronic devices such as memory devices, processor chips (CPUs), graphics chips, and other such devices.

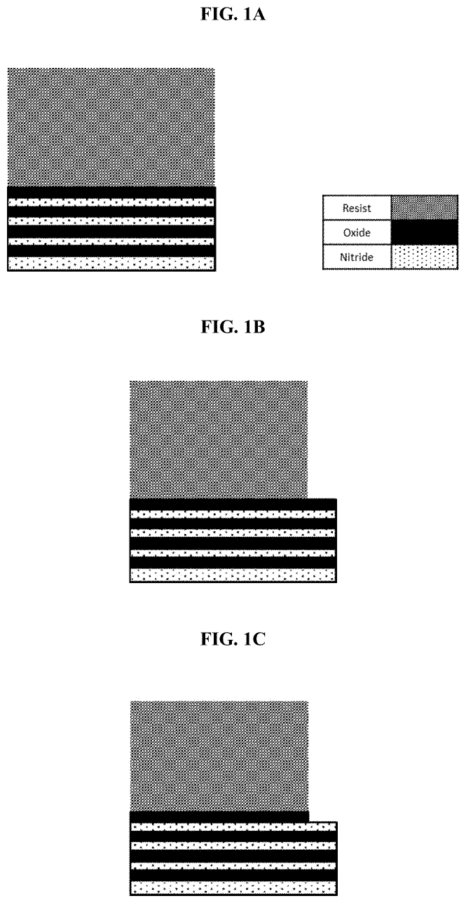

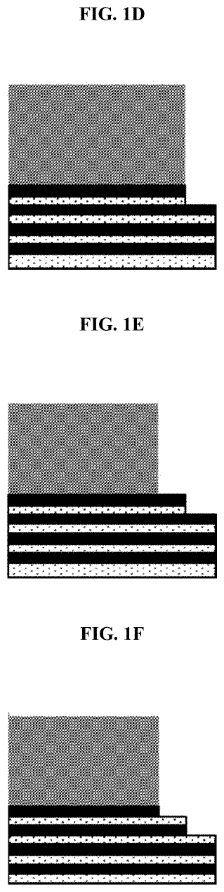

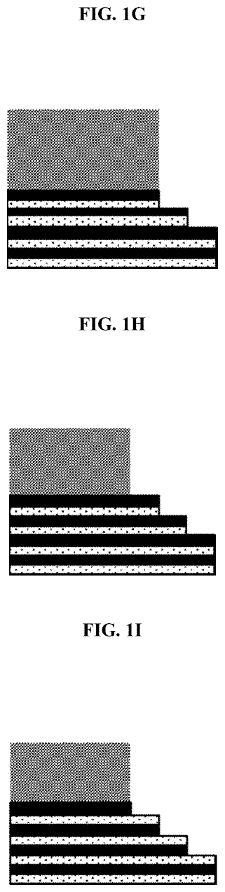

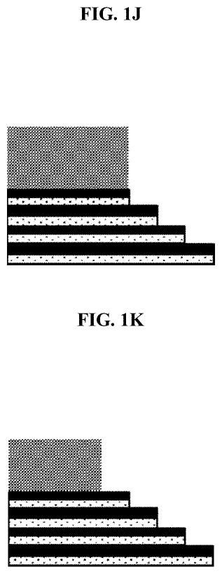

FIGS. 1A to 1K illustrate a method of forming a staircase pattern in accordance with embodiments of the present invention (Hong Xiao “3D IC Devices, Technologies, and Manufacturing” SPIE Press, Bellingham Washington USA).

FIG. 1A shows a structure having a multilayer deposition of alternated silicon oxide (“Oxide”) and silicon nitride (“Nitride”) layers on a silicon surface with a photoresist (“Resist”) layer coated on the wafer surface. The oxide and nitride layers can be formed by various techniques known in the art, for example, chemical vapor deposition (CVD) such as plasma-enhanced CVD (PECVD) or low-pressure CVD (LPCVD). The photoresist layer can be formed as described above. Typically, the photoresist layer is formed by a spin-coating process. The photoresist layer is next patterned by exposure through a patterned photomask and developed as described above, with the resulting structure shown in FIG. 1B. After that, a sequential series of well-controlled oxide and nitride etch and resist trim steps are performed as follows. FIG. 1C shows the structure after the first silicon oxide etch, and FIG. 1D shows the structure after the first silicon nitride etch. After the first pair of oxide and nitride are etched away, a controlled photoresist trim step is performed (FIG. 1E). The trimmed photoresist is then used to etch the first and the second series of oxide and nitride, as shown in FIGS. 1F-G. The photoresist is then trimmed again (FIG. 1H) and the first, second and third pair of oxide/nitride are etched (FIGS. 1I-J). The controlled photoresist trimming is then performed again (FIG. 1K). Suitable oxide and nitride etch and resist trim processes and chemistries are known in the art, with dry-etching processes being typical.

The number of times the photoresist layer can be trimmed may be limited, for example, by its original thickness and etch selectivity. After the minimum thickness limit is reached, the remaining resist is typically stripped and another photoresist layer formed in its place. The new photoresist layer is patterned, the oxide and nitride layers etched, and resist layer trimmed as described above with respect to the original photoresist layer, to continue formation of the staircase pattern. This process can be repeated multiple times until the desired staircase pattern is completed, typically, when the pattern reaches a desired surface of the substrate, typically the silicon surface of the substrate.

The present inventive concept is further illustrated by the following examples. All compounds and reagents used herein are available commercially except where a procedure is provided below.

### EXAMPLES

### Preparation of Photoacid Generators (PAG)

### Example 1: Synthesis of PAG-1

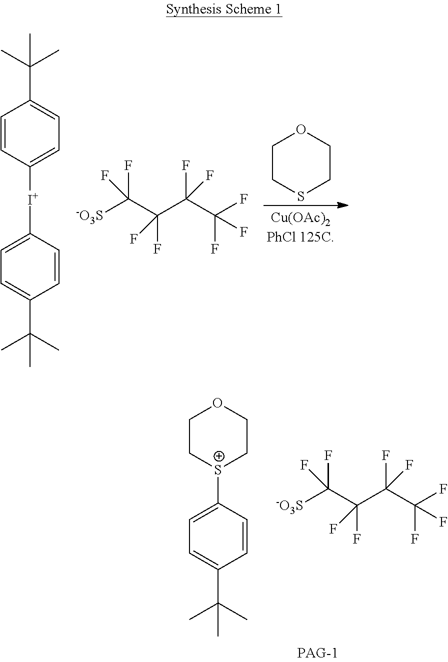

In a 1 L round bottom flask, equipped with a reflux condenser and stirring bar, bis(4-(tert-butyl) phenyl)iodonium perfluorobutanesulfonate (149 g, 216 mmol), and 1,4-oxathiane (25 g, 240 mmol) were dispersed in 400 mL of chlorobenzene. Copper (II) acetate (2.18 g, 12 mmol) was added to the reaction mixture. The reaction was heated at 125° C. for 6 h. The reaction was then cooled to room temperature, diluted with dichloromethane (500 mL), and washed with deionized water (3×200 mL). The organic layer was concentrated to approximatively 100 mL under reduced pressure. Precipitation using methyl tert-butyl ether (MTBE) afforded 105 g of product (81.5%) as a crystalline white solid. ¹H-NMR (600 MHz, CDCl₃) δ 7.88 (d, 2H), 7.69 (d, 2H), 4.38 (m, 2H), 4.11 (m, 2H), 3.93 (m, 2H), 3.67 (m, 2H), 1.34 (s, 9H) ppm. ¹⁹F-NMR (600 MHz, CDCl₃) δ 80.9, 114.66, 12.59, 126.0. ¹³C-NMR (150 MHz, CDCl₃) δ 159.3, 129.8, 128.6, 119.0, 64.2, 39.3, 35.6, 30.9 ppm.

### Example 2

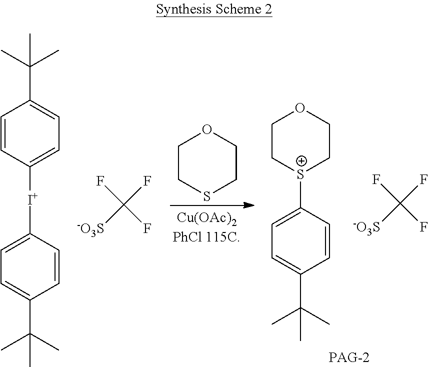

In a 1 L round bottom flask, equipped with a reflux condenser and stirring bar, bis(4-(tert-butyl) phenyl)iodonium trifluoromethanesulfonate (120 g, 220 mmol), and 1,4-oxathiane (25 g, 240 mmol) were dispersed in 200 mL of chlorobenzene. Copper (II) acetate (2.0 g, 11 mmol) was added to the reaction mixture. The reaction was heated at 115° C. for 6 h. The reaction was then cooled to room temperature diluted with dichloromethane (600 mL) and washed with deionized water (3×100 mL). The organic layer was concentrated to approximatively 80 mL under reduced pressure. Precipitation using methyl tert-butyl ether (MTBE) afforded 70.0 g of product (82%) as a crystalline white solid. ¹H-NMR (600 MHz, CDCl₃) δ 7.88 (d, 2H), 7.69 (d, 2H), 4.38 (m, 2H), 4.11 (m, 2H), 3.93 (m, 2H), 3.67 (m, 2H), 1.34 (s, 9H) ppm. ¹⁹F-NMR (600 MHz, CDCl₃) δ 78.4 ppm. ¹³C-NMR (150 MHz-CDCl₃) δ 159.3, 129.8, 128.7, 118.9, 64.2, 39.52, 35.6, 31.0 ppm.

### Example 3

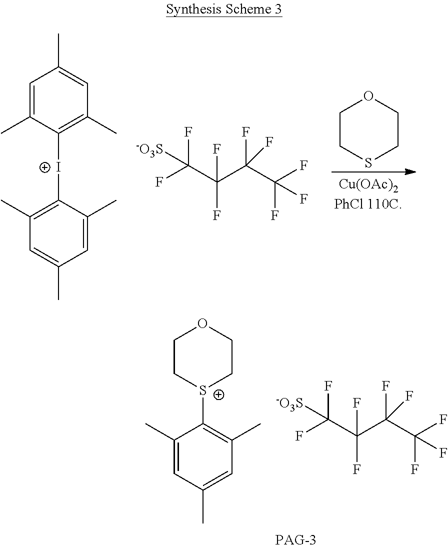

In a 250 mL round bottom flask, equipped with a reflux condenser and stirring bar, bis (mesityl)iodonium perfluorbutanesulfonate (10 g, 15 mmol) and 1,4-oxathiane (2.0 g, 19 mmol) were dispersed in 30 mL of chlorobenzene. Copper (II) acetate (0.1 g, 0.55 mmol) was added to the reaction mixture. The reaction was heated at 110° C. for 5 hours. The reaction was then cooled to room temperature and a precipitate was formed. The precipitate was dissolved with dichloromethane (160 mL) and extracted with deionized water (2×20 mL). The organic layer was separated and concentrated under reduced pressure. Precipitation using methyl tert-butyl ether (MTBE) afforded 5.0 g of product (60%) as a crystalline white solid. ¹H-NMR (600 MHz, CDCl₃) 7.07 (s, 2H), 4.53 (m, 2H), 4.16 (m, 2H), 4.06 (m, 2H), 3.75 (m, 2H), 2.72 (s, 6H), 2.34 (s, 3H) ppm. ¹⁹F-NMR (600 MHz-CDCl₃) 81.0, 114.9, 121.8, 126.1 ppm. ¹³C-NMR (150 MHz-CDCl3) 146.6, 143.2, 132.7, 115.0, 65.9, 36.5, 21.4, 21.2 ppm.

### Preparation of Photoresist Compositions for Photospeed Evaluation

The following polymers and photoacid generators (PAGs) were utilized in the preparation of photoresist compositions in the examples below:

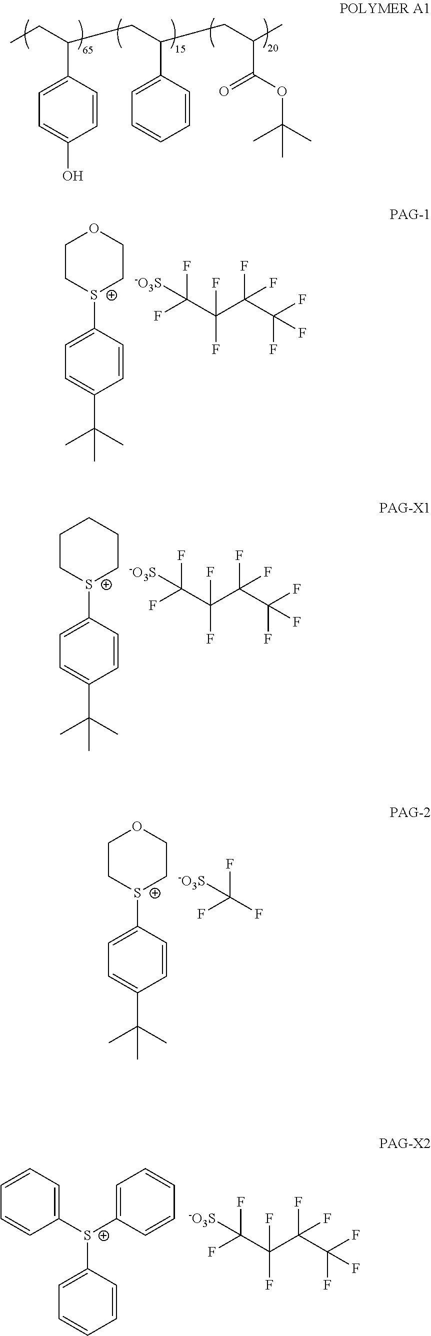

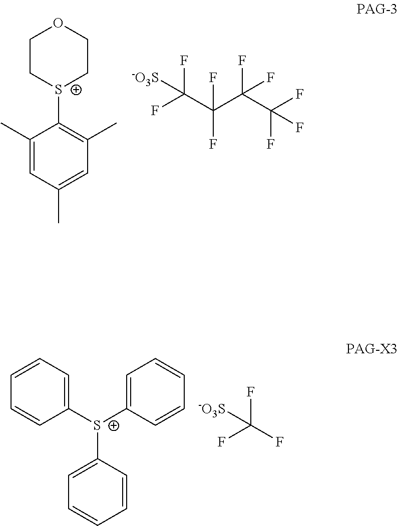

### Example 1

15.392 g of Polymer A1, 0.008 g of POLYFOX® PF-656 surfactant (Omnova Solutions Inc.), 0.006 g of N,N-diethyldodecanamide (DDA), 0.314 g of PAG X1 were dissolved in 19.424 g of propylene glycol monomethyl ether acetate (PGMEA), 3.642 g propylene glycol monomethyl ether (PGME), and 1.214 g of gamma-butyrolactone (GBL). The resulting mixture was rolled on a roller for 12 hours, and then, filtered through a Teflon filter having a 1 micron pore size.

### Examples 2-6

The photoresist compositions were prepared by using the same procedure as Example 1, using the components and amounts set forth in Table 1.

KrF contrast and lithographic evaluations were carried out on 200 mm silicon wafers using a TEL Mark 8 track. To begin, silicon wafers were primed with HMDS (at 180° C./60 sec). HMDS-primed wafers were spin-coated with the aforementioned compositions and baked at 150° C. for 70 sec to yield a film thickness of ˜13 micron (μm). The photoresist-coated wafers were then exposed using an ASML 300 KrF stepper through an open frame mask. The exposure started at 1.0 mJ/cm² and increased by an increment of 1.0 mJ/cm² to expose 100 dies in a 10×10 array on the wafer. The exposed wafers were post-exposure baked at 110° C. for 50 seconds and then developed using 0.26 Normal tetramethylammonium hydroxide solution (CD-26) for 45 seconds. The remaining film thickness at different exposure doses was measured on a ThermaWave Optiprobe (KLA-Tencor), and the remaining film thickness was plotted as a function of exposure energy to obtain KrF positive tone contrast curves. The contrast curves were used to determine the clearing dose (E₀) which is the minimum dose that is required to clear the film completely. The E₀ value for each formulation is shown in Table 1.

TABLE 1

| | Polymer | PAG | Quench- | Sur- | Solvent A | Solvent B | Solvent C | Solvent D | E₀ |
|---|---|---|---|---|---|---|---|---|---|
| Ex- | #1 | #1 | er | factant | (PGMEA) | (PGME) | (GBL) | (HBM) | (mJ/ |
| amples | (g) | (g) | (g) | (g) | (g) | (g) | (g) | (g) | Cm²) |
| 1 | A1 | PAG-X1 | 0.006 | 0.008 | 19.424 | 3.642 | 1.214 | NA | >100 |
| (Comp) | (15.392) | (0.314 g) | | | | | | | |
| 2 | A1 | PAG-X2 | 0.006 | 0.008 | 19.416 | 3.641 | 1.214 | NA | >100 |
| (Comp) | (15.385) | (0.331 g) | | | | | | | |
| 3 | A1 | PAG-1 | 0.006 | 0.008 | 19.423 | 3.642 | 1.214 | NA | 77 |
| | (15.392) | (0.316 g) | | | | | | | |
| 4 | A1 | PAG-X3 | 0.006 | 0.008 | 19.457 | 3.648 | 1.216 | NA | >100 |
| (Comp) | (15.424) | (0.242 g) | | | | | | | |
| 5 | A1 | PAG-2 | 0.006 | 0.008 | 19.464 | 3.649 | 1.216 | NA | 84 |
| | (15.430) | (0.227 g) | | | | | | | |
| 6 | A1 | PAG-3 | 0.006 | 0.008 | 18.737 | 3.650 | 1.217 | 0.730 | 65 |
| | (15.346) | (0.306 g) | | | | | | | |

“Comp” = comparative example.
“HBM” = methyl-2-hydroxyisobutyrate

The oxathianium photoacid generators display unexpectedly faster photospeed in comparison to both cycloalkylsulfonium and TPS photoacid generators at 248 nm in thick film photoresists (1-20 μm). This unexpected behavior is due to an optimal balance between transparency at 248 nm and photoacid generation ability at 248 nm.

### Lithographic Evaluation

The following polymers and photoacid generators (PAGs) were utilized in the preparation of photoresist compositions in the examples below:

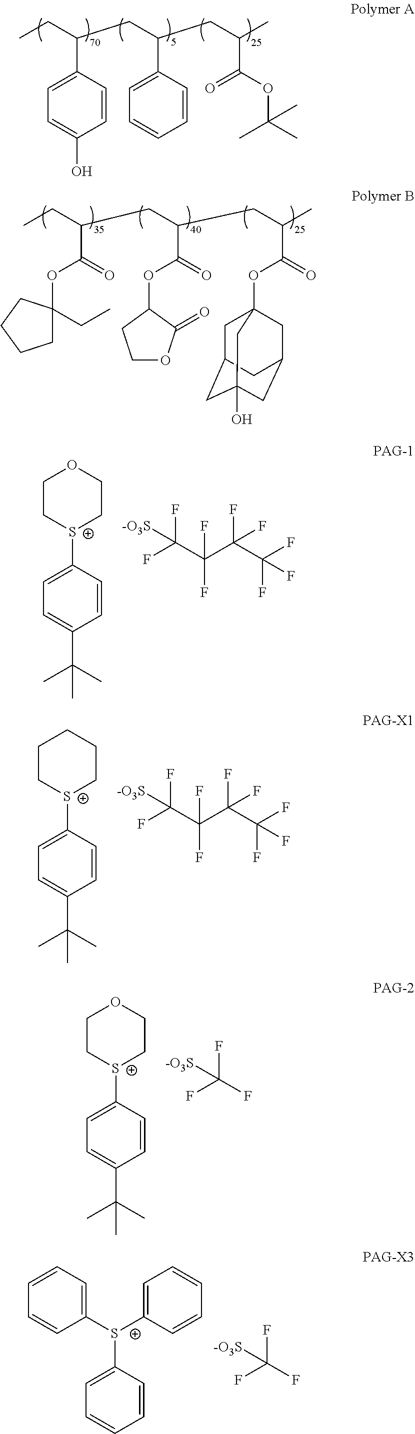

### Example 1

15.787 g of Polymer A and 3.947 g of Polymer B, 0.010 g of POLYFOX® PF-656 surfactant (Omnova Solutions Inc.), and 0.007 g of 1-allylazepan-2-one were dissolved in 24.000 g of propylene glycol monomethyl ether acetate (PGMEA). To this mixture was added 0.200 g of PAG X1 and 0.050 g of PAG X3 described above dissolved in 4.500 g propylene glycol monomethyl ether (PGME). 1.500 g of gamma-butyrolactone (GBL) was added to the resulting mixture. The final mixture was rolled on a roller for 12 hours and then filtered through a Teflon filter having a 1 micron pore size.

Photoresist compositions 2-4 were prepared using the same procedures as Example 1, using the components and amounts as set forth in Table 2.

TABLE 2

| | | | | | | | Sol- | Sol- | Sol- |
|---|---|---|---|---|---|---|---|---|---|
| Ex- | Polymer | Polymer | PAG | PAG | Quench- | Sur- | vent | vent | vent |
| amples | #1 | #2 | #1 | #2 | er | factant | A | B | C |
| 1 | A | B | PAG X1 | PAG X3 | 0.007 | 0.010 | 24.000 | 4.500 | 1.500 |
| (Comp) | (15.787) | (3.947) | (0.200) | (0.050) | | | | | |
| 2 | A | B | PAG 1 | PAG X3 | 0.007 | 0.010 | 24.000 | 4.500 | 1.500 |
| | (15.549) | (3.887) | (0.198) | (0.049) | | | | | |
| 3 | A | B | PAG X1 | PAG 2 | 0.007 | 0.010 | 24.000 | 4.500 | 1.500 |
| | (15.821) | (3.955) | (0.200) | (0.047) | | | | | |
| 4 | A | B | PAG 1 | PAG 2 | 0.007 | 0.010 | 24.000 | 4.500 | 1.500 |
| | (15.369) | (3.842) | (0.195) | (0.046) | | | | | |

Quencher: 1-allylazepan-2-one;
Surfactant: POLYFOX ® PF-656 (Omnova Solutions Inc.);
Solvent A: propylene glycol monomethyl ether acetate (PGMEA);
Solvent B: propylene glycol methyl ether (PGME);
Solvent C: gamma-butyrolactone (GBL).
All contents in grams.
“Comp” = comparative example.

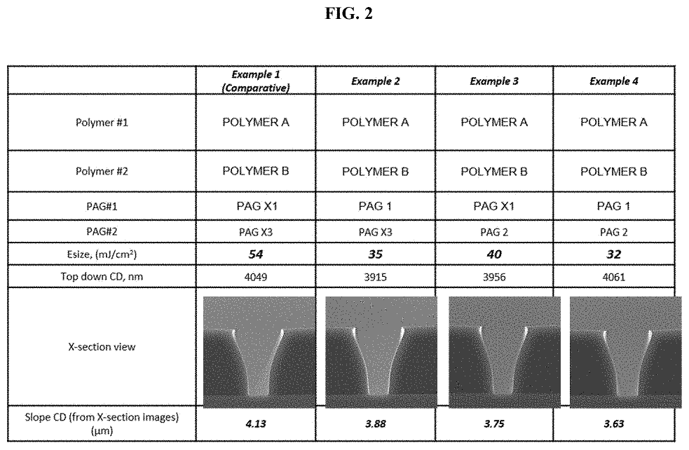

KrF lithographic evaluations were carried out on 200 mm silicon wafers using a TEL Mark 8 track. Initially, silicon wafers were primed with HMDS (at 180° C./60 sec). HMDS-primed wafers were then spin-coated with the aforementioned compositions and baked at 150° C. for 70 sec to yield a film having a thickness of ˜13 micron (m). The photoresist-coated wafers were then exposed using an ASML 300 KrF stepper with a binary mask using 0.52NA. The exposed wafers were post-exposure baked at 110° C. for 50 seconds, and then, developed using 0.26 Normal tetramethylammonium hydroxide solution (CD-26) for 45 seconds. KrF Lithographic results are summarized in the FIG. 2, where “E_{size}” is the sizing energy expressed in units of mJ/cm². In comparison to Example 1 (Comparative), the photoresist compositions of Examples 2, 3, and 4 exhibited faster photospeed and also, as evident from the CD SEM views in the FIG. 2, a narrower slope CD (calculated as the CD difference in μm between the top and the bottom of the film for a specific patterned feature).

The oxathianium photoacid generators display unexpectedly faster photospeed in comparison to both cycloalkylsulfonium and TPS photoacid generators at 248 nm in thick film photoresists (1-20 μm). This unexpected behavior is due to an optimal balance between transparency at 248 nm and photoacid generation ability at 248 nm, which allows for better light penetration in the resist coupled with a good photoacid generation efficiency at 248 nm and fast acid diffusion due to the small size of the PAG anion, leading to improved lithography in thick film resist.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A photoresist composition, comprising:
a polymer;
a solvent; and
a sulfonium salt having Formula (I): 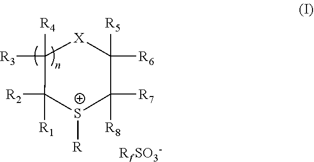
wherein:
R is an unsubstituted or substituted C₂₋₂₀ alkenyl group, an unsubstituted or substituted C₃₋₂₀ cycloalkyl group, an unsubstituted or substituted C₅₋₃₀ aromatic group, or an unsubstituted or substituted C₄₋₃₀ heteroaromatic group, wherein R optionally includes an acid-sensitive functional group capable of being hydrolyzed at pH<7.0;
R₁ to R₈ are each independently hydrogen, a halogen selected from fluorine, chlorine, bromine, and iodine, a straight chain or branched C₁₋₂₀ alkyl group, a straight chain or branched C₁₋₂₀ fluoroalkyl group, a straight chain or branched C₂₋₂₀ alkenyl group, a straight chain or branched C₂₋₂₀ fluoroalkenyl group, a monocyclic or polycyclic C₃₋₂₀ cycloalkyl group, a monocyclic or polycyclic C₃₋₂₀ fluorocycloalkyl group, a monocyclic or polycyclic C₃₋₂₀ cycloalkenyl group, a monocyclic or polycyclic C₃₋₂₀ fluorocycloalkenyl group, a monocyclic or polycyclic C₃₋₂₀ heterocycloalkyl group; a monocyclic or polycyclic C₃₋₂₀ heterocycloalkenyl group; a monocyclic or polycyclic C₆₋₂₀ aryl group, a monocyclic or polycyclic C₆₋₂₀ fluoroaryl group, a monocyclic or polycyclic C₄₋₂₀ heteroaryl group, or a monocyclic or polycyclic C₄₋₂₀ fluoroheteroaryl group, each of which except hydrogen is substituted or unsubstituted,
wherein any two of R₁ to R₈ are optionally connected via Z to form a ring, wherein Z is a single bond or at least one linker selected from —C(═O)—, —S(═O)—, —S(═O)₂—, —C(═O)O—, —C(═O)NR′—, —C(═O)—C(═O)—, —O—, —CH(OH)—, —CH₂—, —S—, and —BR′—, wherein R′ is hydrogen or a C₁₋₂₀ alkyl group,
wherein each of R₁ to R₈ are optionally substituted with at least one selected from —OY, —NO₂, —CF₃, —C(═O)—C(═O)—Y, —CH₂OY, —CH₂Y, —SY, —B(Y)ₙ, —C(═O)NRY, —NRC(═O)Y, —(C═O)OY, and —O(C═O)Y, wherein Y is a straight chain or branched C₁₋₂₀ alkyl group, a straight chain or branched C₁₋₂₀ fluoroalkyl group, a straight chain or branched C₂₋₂₀ alkenyl group, a straight chain or branched C₂₋₂₀ fluoroalkenyl group, a straight chain or branched C₂₋₂₀ alkynyl group, a straight chain or branched C₂₋₂₀ fluoroalkynyl group, a C₆₋₂₀ aryl group, a C₆₋₂₀ fluoroaryl group, or an acid-sensitive functional group capable of being hydrolyzed at pH<7.0;
X is O, S, Se, Te, NR″, S═O, S(═O)₂, C═O, (C═O)O, O(C═O), (C═O)NR″, or NR′(C═O), wherein R″ is hydrogen or a C₁₋₂₀ alkyl group;
n is an integer of 0 to 5; and
R_{f} is a linear or branched or cyclic C₁₋₆ fluorinated alkyl group.

2. The photoresist composition of claim 1, wherein R_{f} in Formula (I) is —C(R₉)_{y}(R₁₀)_{z}, wherein R₉ is independently selected from F and fluorinated methyl, R₁₀ is independently selected from H, C₁₋₅ linear or branched or cyclic alkyl and C₁₋₅ linear or branched or cyclic fluorinated alkyl, y and z are independently an integer from 0 to 3, provided that the sum of y and z is 3, and at least one of R₉ and R₁₀ contains fluorine, wherein the total number of carbon atoms in R_{f} is from 1 to 6.

3. The photoresist composition of claim 1, wherein R is an unsubstituted or substituted C₅₋₃₀ aromatic group or an unsubstituted or substituted C₄₋₃₀ heteroaromatic group.

4. The photoresist composition of claim 3, wherein R is a substituted phenyl group.

5. The photoresist composition of claim 4, wherein one or more substituents of R are selected from C₁₋₅ alkyl, C₃₋₆ cycloalkyl, and a combination thereof.

6. The photoresist composition of claim 1, wherein each of R₁ to R₈ is hydrogen.

7. The photoresist composition of claim 1, wherein the polymer comprises structural units formed from a substituted or unsubstituted styrene monomer in an amount of equal to or greater than 50 weight percent based on 100 weight percent of the total amount of structural units in the polymer.

8. The photoresist composition of claim 1, wherein X is O.

9. The photoresist composition of claim 1, wherein the photoresist composition is capable of being coated in a single application to a thickness in a dried state of greater than 5.0 microns and less than 30 microns.

10. A coated substrate, comprising: (a) a substrate, and (b) a layer of the photoresist composition of claim 1 disposed over the substrate.

11. A method of forming a resist pattern, the method comprising: (a) applying a layer of the photoresist composition of claim 1 on a substrate; (b) drying the applied photoresist composition to form a composition layer; (c) exposing the composition layer to activating radiation; (d) heating the exposed composition layer; and (e) developing the exposed composition layer.

12. The method of claim 11, wherein the layer of the photoresist composition is coated in a single application to a thickness of greater than 5.0 microns and less than 30 microns.

13. The method of claim 11, further comprising forming a staircase pattern in the substrate using the composition layer as an etch mask, wherein the staircase pattern comprises a plurality of stairs.
